(19) United States
(12) Patent Application Publication
(10) Pub. No.: US 2012/0114840 A1
(43) Pub. Date: May 10, 2012

(54) VACUUM VAPOR DEPOSITION SYSTEM

(75) Inventors: Naoto Fukuda, Chiba-shi (JP); Yoshiyuki Nakagawa, Chiba-shi (JP); Shingo Nakano, Chiba-shi (JP)

(73) Assignee: CANON KABUSHIKI KAISHA, Tokyo (JP)

(21) Appl. No.: 13/284,040

(22) Filed: Oct. 28, 2011

(30) Foreign Application Priority Data
Nov. 4, 2010 (JP) 2010-247817
Sep. 28, 2011 (JP) 2011-211797

(51) Int. Cl. C23C 16/52; C23C 16/455

(52) U.S. Cl. 427/9; 118/665

(57) ABSTRACT

Provided is a vacuum vapor deposition system including: a vapor depositing source; a film thickness sensor for monitoring; and a film thickness sensor for calibration, in which a distance L₁ from a center of an opening of the vapor depositing source to the film thickness sensor for calibration and a distance L₂ from the center to the film thickness sensor for monitoring satisfy a relationship of L₁≦L₂, and angle θ₁ formed by a perpendicular line from the center of the opening of the vapor deposition source to a film formation surface of the substrate and a straight line connecting the center of the opening of the vapor depositing source to the film thickness sensor for calibration, and angle θ₂ formed by the perpendicular line and a straight line connecting the center of the opening of the vapor depositing source to the film thickness sensor for monitoring satisfy a relationship of θ₁≦θ₂.

### BACKGROUND OF THE INVENTION

1. Field of the Invention

The present invention relates to a vacuum vapor deposition system, and more particularly, to a vacuum vapor deposition system for producing an organic electroluminescence (EL) element.

2. Description of the Related Art

An organic EL element is generally an electronic element in which an organic thin film layer formed of a hole transport layer, a emission layer, an electron transport layer, and the like are provided between an electrode made of a transparent conductive film (for example, indium tin oxide) and an electrode made of metal (for example, Al). When excitons generated by the recombination of holes injected from the anode side and electrons injected from the cathode side in the emission layer respectively through the hole transport layer and the electron transport layer return to the ground state, the organic light-emitting element emits light.

Meanwhile, as one of the methods of producing an organic EL element, a vacuum vapor deposition method is known. For example, a constituent material (vapor deposition material) for an organic EL element is placed in a crucible and heated to a temperature equal to or more than a vaporization temperature of the vapor deposition material in a vacuum system to generate vapor of the vapor deposition material, and the vapor deposition material is deposited on a substrate serving as a base of the organic EL element to form an organic thin film layer.

It is known that, in the step of producing an organic EL element using the vacuum vapor deposition method, a vapor deposition rate is monitored by a film thickness sensor using a crystal oscillator to control the evaporation amount (generation amount of vapor) of the vapor deposition material. This is because, if the vapor deposition rate is not monitored, the adhesion amount of the vapor deposition material to the substrate during film formation (film thickness of a thin film to be formed on the substrate) is unclear, which makes it difficult to adjust the film thickness on the substrate to a target value.

However, as the adhesion amount of the vapor deposition material to the crystal oscillator increases, a difference is caused between the vapor deposition rate value indicated by the film thickness sensor and the adhesion amount of the vapor deposition material on the substrate. This is attributed to a change in frequency of the crystal oscillator along with an increase in the vapor deposition material adhering to the crystal oscillator. This phenomenon becomes a problem particularly in the case where the allowable range of an error of the film thickness of the thin film to be formed on the substrate with respect to the target value is small. As the film thickness per layer of the organic EL element is generally about tens of nm to 100 nm, the allowable range of an error of the film thickness with respect to the target value is on the order of several nanometers. Then, the difference between the vapor deposition rate value and the adhesion amount of the vapor deposition material on the substrate (film thickness of the thin film formed on the substrate) may cause a decrease in production yield.

As means for solving the above-mentioned problem, there is known a vacuum vapor deposition system provided with a film thickness sensor for controlling a film thickness and a film thickness sensor for calibrating a film thickness, disclosed in Japanese Patent Application Laid-Open No. 2008-122200. In the vacuum vapor deposition system of Japanese Patent Application Laid-Open No. 2008-122200, a measurement error of the film thickness sensor for controlling a film thickness is calibrated by the film thickness sensor for calibrating a film thickness so as to keep the vapor deposition rate constant. Thus, the adhesion amount of the vapor deposition material to the substrate can fall within the target value stably.

Meanwhile, Japanese Patent Application Laid-Open No. 2008-122200 discloses that the distances between the vapor depositing source and the respective sensors are equal. However, in general, the distribution of the vapor deposition material evaporating from an opening of the vapor depositing source becomes an oval sphere (according to a COS rule). Considering this, in the arrangement of the sensors of the vacuum vapor deposition system of Japanese Patent Application Laid-Open No. 2008-122200, there is a possibility that the adhesion amount of the vapor deposition material entering the film thickness sensor for calibrating a film thickness to be used intermittently may decrease, and hence, the construction is insufficient for enhancing the calibration accuracy.

### SUMMARY OF THE INVENTION

The present invention has been made to solve the above-mentioned problem. An object of the present invention is to provide a vacuum vapor deposition system, which enables a vapor deposition rate to be measured accurately and a film thickness to be controlled with higher accuracy.

A vacuum vapor deposition system of the present invention includes: a vacuum chamber; a substrate holding mechanism which holds a substrate; a vapor depositing source which generates vapor of a vapor deposition material to be formed into a film on the substrate; a film thickness sensor for monitoring which measures an adhesion amount of the vapor deposition material adhering to a sensor portion when the vapor deposition material is formed into a film on the substrate; a control system which controls the temperature of the vapor depositing source based on measured data obtained by the film thickness sensor for monitoring; and a film thickness sensor for calibration which measures the vapor deposition rate of the vapor deposition material and outputs a calibration value for calibrating the measured data obtained by the film thickness sensor for monitoring to the control system, in which a distance L₁ from a center of an opening of the vapor depositing source to the film thickness sensor for calibration and a distance L₂ from the center of the opening of the vapor depositing source to the film thickness sensor for monitoring satisfy a relationship of L₁≦L₂, and an angle θ₁ formed by a perpendicular line from the center of the opening of the vapor depositing source to a film formation surface of the substrate and a straight line connecting the center of the opening of the vapor depositing source to the film thickness sensor for calibration, and an angle θ₂ formed by a perpendicular line from the center of the opening of the vapor depositing source to the film formation surface of the substrate and a straight line connecting the center of the opening of the vapor depositing source to the film thickness sensor for monitoring satisfy a relationship of θ₂≧θ₁.

According to the present invention, it is possible to provide the vacuum vapor deposition system, which enables a vapor deposition rate to be measured accurately and a film thickness to be controlled with higher accuracy.

Specifically, in the vacuum vapor deposition system of the present invention, the film thickness sensor for calibration is placed at a position with high calibration accuracy, and the vapor depositing source is controlled based on the measured data obtained by the film thickness sensor for monitoring to be calibrated intermittently. This construction enables the vapor deposition rate of the vapor deposition material formed into a film on the substrate to be monitored with high accuracy and the production yield of an organic EL element to be enhanced.

Further features of the present invention will become apparent from the following description of exemplary embodiments with reference to the attached drawings.

### BRIEF DESCRIPTION OF THE DRAWINGS

FIGS. 1A and 1B are schematic diagrams each illustrating a first embodiment of a vacuum vapor deposition system of the present invention. FIG. 1A is a schematic diagram illustrating the entire vacuum vapor deposition system, and FIG. 1B is a circuit block diagram illustrating an outline of a control system constructing the vacuum vapor deposition system of FIG. 1A.

FIG. 2 is a flow chart illustrating an example of a calibration step.

FIG. 3 is a schematic diagram illustrating a second embodiment of the vacuum vapor deposition system of the present invention.

FIG. 4 is a schematic diagram illustrating a third embodiment of the vacuum vapor deposition system of the present invention.

FIG. 5 is a schematic diagram illustrating a fourth embodiment of the vacuum vapor deposition system of the present invention.

### DESCRIPTION OF THE EMBODIMENTS

A vacuum vapor deposition system of the present invention includes: a vacuum chamber; a substrate holding mechanism; a vapor depositing source; a film thickness sensor for monitoring; a control system; and a film thickness sensor for calibration.

Here, the substrate holding mechanism is a member for holding a substrate. The vapor depositing source is a member for generating vapor of a vapor deposition material to be formed into a film on the substrate. The film thickness sensor for monitoring is a member for measuring the vapor deposition rate of the vapor deposition material of interest and controlling the temperature of the vapor depositing source when the vapor deposition material is formed into a film on the substrate. The control system is a member for controlling the temperature of the vapor depositing source based on measured data obtained by the film thickness sensor for monitoring. The film thickness sensor for calibration is a member for measuring the vapor deposition rate of the vapor deposition material and outputting a calibration value for calibrating the measured data obtained by the film thickness sensor for monitoring to the control system.

In the vacuum vapor deposition system of the present invention, a distance L₁ from a center of an opening of the vapor depositing source to the film thickness sensor for calibration and a distance L₂ from the center of the opening of the vapor depositing source to the film thickness sensor for monitoring satisfy a relationship of L₁≦L₂. The distance used herein refers to a linear distance between two members. Specifically, in the case where the (center of the opening of) the vapor depositing source and each of the sensors (film thickness sensor for monitoring and film thickness sensor for calibration) are placed respectively at (x₁, y₁, z₁) and (x₂, y₂, z₂) in particular space coordinates (xyz space coordinates), the distance is represented by d in Expression (i) below.

d={(x₂−x₁)²+(y₂−y₁)²+(z₂−z₁)²}^{1/2} (i)

It should be noted that the coordinates (x₂, y₂, z₂) on the sensor side specifically refer to coordinates of a center of the film formation surface of the sensor.

Here, an angle formed by a perpendicular line from the center of the opening of the vapor depositing source to the film formation surface of the substrate and a straight line connecting the center of the opening of the vapor depositing source to the film thickness sensor for calibration is defined as θ₁. On the other hand, an angle formed by a perpendicular line from the center of the opening of the vapor depositing source to the film formation surface of the substrate and a straight line connecting the center of the opening of the vapor depositing source to the film thickness sensor for monitoring is defined as θ₂. In the vacuum vapor deposition system of the present invention, the angle θ₁ and the angle θ₂ satisfy a relationship of θ₂≧θ₁.

### Example 1

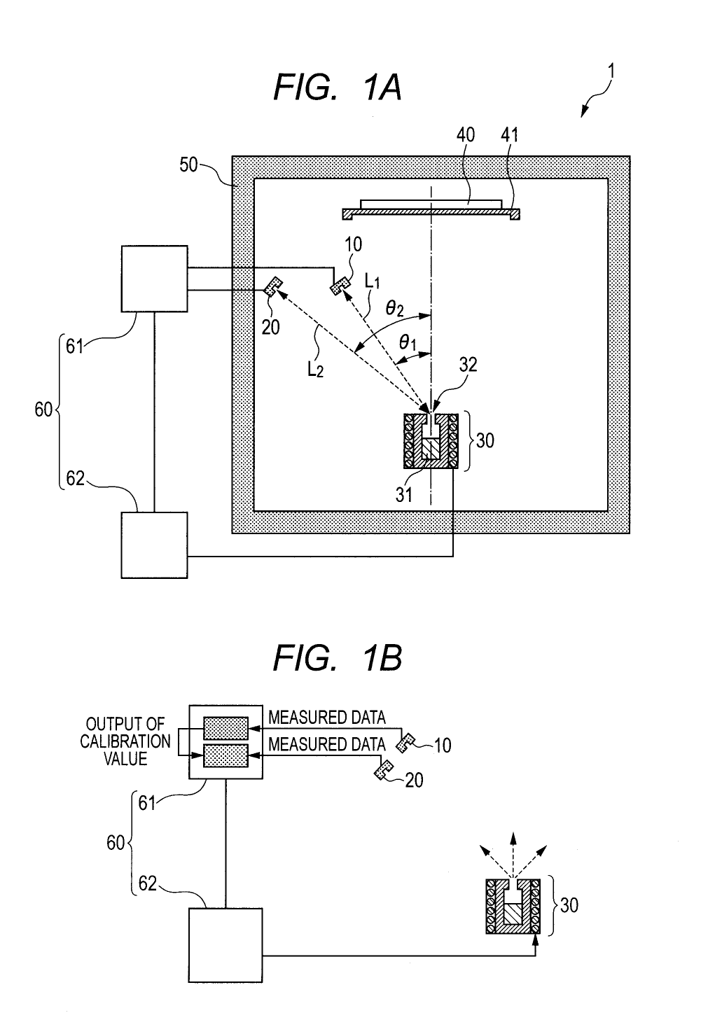

Hereinafter, embodiments of the present invention are described with reference to the drawings. FIGS. 1A and 1B are schematic diagrams each illustrating a first embodiment of the vacuum vapor deposition system of the present invention. Here, FIG. 1A is a schematic diagram illustrating the entire vacuum vapor deposition system, and FIG. 1B is a circuit block diagram illustrating an outline of a control system constructing the vacuum vapor deposition system of FIG. 1A. In a vacuum vapor deposition system 1 of FIG. 1A, a film thickness sensor for calibration 10, a film thickness sensor for monitoring 20, a vapor depositing source 30, and a substrate holding mechanism (not shown) are provided at predetermined positions in a vacuum chamber 50. It should be noted that the relative positions of the film thickness sensor for calibration 10 and the film thickness sensor for monitoring with respect to the vapor depositing source 30 are described later.

In the vacuum vapor deposition system 1 of FIG. 1A, the substrate holding mechanism is a member provided so as to hold a substrate 40 and holds the substrate 40 placed on a mask 41 by supporting the mask 41. A control system 60 is provided outside of the vacuum chamber 50 and has a film thickness controller 61 and a temperature controller 62. As illustrated in FIGS. 1A and 1B, two kinds of sensors (film thickness sensor for calibration 10 and film thickness sensor for monitoring 20) provided in the vacuum chamber 50 are electrically connected to the film thickness controller 61. Further, as illustrated in FIGS. 1A and 1B, the vapor depositing source 30 provided in the vacuum chamber 50 is electrically connected to the temperature controller 62.

The vapor depositing source 30 includes a crucible for accommodating a vapor deposition material 31, a heater for heating the crucible, a lid, an opening 32 provided in the lid, and a reflector. The vapor deposition material 31 is heated in the crucible, and vapor is discharged through the opening 32 provided in the lid. The vapor of the vapor deposition material generated from the vapor depositing source 30 adheres to a film formation surface of the substrate 40 for forming a film through the mask 41. Thus, a thin film is formed in a predetermined area of the substrate 40.

The speed (vapor deposition rate) at which the vapor of the vapor deposition material generated from the vapor depositing source 30 is deposited on the substrate 40 is calculated from the adhesion amount of the vapor deposition material adhering to a sensor portion (not shown) of the film thickness sensor for monitoring 20 provided with a crystal oscillator. The film thickness sensor for monitoring 20 outputs the adhesion amount of the vapor deposition material adhering to the sensor portion, that is, measured data to the film thickness controller 61. The film thickness controller 61 calculates a vapor deposition rate based on the output measured data of the film thickness sensor for monitoring 20 and controls the heater power of the vapor depositing source 30 using the temperature controller 62. Meanwhile, in order to output a calibration value for calibrating the measured data of the film thickness sensor for monitoring 20, the film thickness sensor for calibration 10 provided with the crystal oscillator is provided. Here, the two sensors (film thickness sensor for calibration 10 and film thickness sensor for monitoring 20) are placed at positions where the sensors do not block the vapor of the vapor deposition material generated from the vapor depositing source 30 and directed to the substrate 40.

Here, a distance from a center of the opening 32 to a center of a film formation surface of the film thickness sensor for calibration 10 is defined as L₁. On the other hand, a distance from the center of the opening to a center of a film formation surface of the film thickness sensor for monitoring 20 is defined as L₂. In the vacuum vapor deposition system 1 of FIG. 1A, L₂ is larger than L₁ (L₁<L₂), and the relationship of L₁≦L₂ is satisfied.

Further, an angle formed by a perpendicular line from the center of the opening 32 to the film formation surface of the substrate 40 and a straight line connecting the center of the opening 32 to the center of the film formation surface of the film thickness sensor for calibration 10 is defined as θ₁. On the other hand, an angle formed by a perpendicular line from the center of the opening 32 to the film formation surface of the substrate 40 and a straight line connecting the center of the opening 32 to the center of the film formation surface of the film thickness sensor for monitoring 20 is defined as θ₂. In the vacuum vapor deposition system 1 of FIG. 1A, θ₂ is larger than θ₁ (θ₁<θ₂), and the relationship of θ₂≦θ₂ is satisfied. It should be noted that, in order to enhance the sensitivity of each of the sensors, it is preferred to adjust the setting positions so that the film formation surface of each of the film thickness sensors is perpendicular to the straight line connecting the center of the film formation surface to the center of the opening 32 when each of the film thickness sensors is provided.

In the vacuum vapor deposition system 1 of FIG. 1A, at least one of the film thickness sensor for calibration 10 and the film thickness sensor for monitoring 20 may be provided with a sensor shutter (not shown) for blocking the vapor of the vapor deposition material 31. Further, a vapor deposition amount restricting mechanism (not shown) for blocking the vapor of the vapor deposition material 31 intermittently may be provided instead of the sensor shutter.

In the vacuum vapor deposition system 1 of FIG. 1A, an alignment mechanism (not shown) may be provided in the vacuum chamber 50 so as to form a fine pattern using a high-precision mask and precision alignment vapor deposition in combination.

A vacuum evacuation system (not shown) for evacuating the vacuum chamber 50 of air is desirably a vacuum evacuation system using a vacuum pump having an ability to evacuate the vacuum chamber of air to a high vacuum area rapidly. Here, in the case of using the vacuum vapor deposition system 1 of FIG. 1A for the production of an organic EL element, the vacuum vapor deposition system 1 is connected to another vacuum device through a gate valve (not shown), and various steps for producing an organic EL element may be conducted. Here, in an apparatus for producing an organic EL element, it is desired that multiple vacuum chambers conducting various steps be provided. Therefore, it is desired that the vacuum chamber 50 constructing the vacuum vapor deposition system 1 of FIG. 1A be one member of the apparatus for producing an organic EL element.

The opening area, opening shape, material, and the like of the opening 32 provided in the lid of the vapor depositing source 30 may vary individually, and the opening shape may be any shape such as a circle shape, a rectangle shape, an oval shape. Due to the variation in the opening area and opening shape, the film thickness controllability on the substrate 40 may be enhanced further. Further, for the same reason, the shape, material, and the like of the crucible of the vapor depositing source 30 may vary individually.

An example of producing an organic EL layer of an organic EL element provided in an organic light-emitting device using the vacuum vapor deposition system 1 of FIG. 1A is described below. The organic EL element includes a first electrode, a second electrode, and an organic EL layer surrounded by the electrodes.

First, 10.0 g of tris(8-hydroxyquinolinato) aluminum (hereinafter, referred to as Alq₃) as an organic EL material were loaded as the vapor deposition material 31 into a crucible of the vapor depositing source 30. Alqₐ loaded into the crucible of the vapor depositing source 30 is evaporated from the vapor depositing source 30 via at least one opening 32 provided in the vapor depositing source 30. Here, the vapor depositing source 30 is placed opposed to the film formation surface of the substrate 40, and the substrate 40 is set in contact with the mask 41. Further, the distance from the center of the opening 32 of the vapor depositing source 30 to the film formation surface of the substrate 40 was set to 300 mm.

The film thickness sensor for calibration 10 and the film thickness sensor for monitoring 20 were placed at positions where the sensors did not block the vapor directed to the substrate 40 and generated from the vapor depositing source 30. Specifically, in the film thickness sensor for calibration 10, L₁ and θ₁ were set to 200 mm and 30°. On the other hand, in the film thickness sensor for monitoring 20, L₂ and θ₂ were set to 300 mm and 45°. As the distribution of the vapor deposition material varies depending upon the vapor deposition condition, L₁, L₂, θ₁, and θ₂ need to be determined appropriately depending upon the vapor deposition condition. It should be noted that a sensor shutter (not shown) was provided in the vicinity of the film thickness sensor for calibration 10 so as to block the vapor of the vapor deposition material appropriately.

Meanwhile, the vapor amount of the vapor deposition material 31 generated from the vapor depositing source 30 is larger at a place having a shorter distance from the perpendicular line from the center of the opening 32 to the film formation surface of the substrate 40, and the vapor amount is larger at a place closer to the center of the opening 32. By placing the film thickness sensor for calibration 10 and the film thickness sensor for monitoring 20 according to the above-mentioned conditions, the entry amount of the vapor deposition material 31 to the film thickness sensor for calibration 10 increases as compared to that to the film thickness sensor for monitoring 20. As the entry amount of the vapor deposition material 31 to the film thickness sensor for calibration 10 increases in this manner, the difference from the thickness of a thin film to be formed on the substrate decreases, which can enhance the calibration accuracy of the film thickness sensor for calibration 10. Further, as the entry amount of the vapor deposition material 31 to the film thickness sensor for monitoring 20 is relatively small, the film thickness sensor for monitoring 20 can be used for a long period of time with a change ratio of a frequency of the crystal oscillator reduced.

As the substrate 40, multiple glass substrates with a dimension of 100 mm×100 mm×0.7 mm (thickness) provided with a circuit and a first electrode for driving an organic light-emitting device were set in a substrate stock device (not shown).

Next, the substrate stock device was evacuated to 1.0×10⁻⁴ Pa or less by a vacuum evacuation system (not shown). The vacuum chamber 50 was also evacuated to 1.0×10⁻⁴ Pa or less by the vacuum evaluation system (not shown), and after the evacuation, the vapor deposition material 31 was heated to 200° C. by a heater provided in the vapor depositing source 30. The heater power was controlled by the temperature controller 62 based on the temperature of a thermocouple (not shown) provided in the vapor depositing source 30.

Before using the film thickness sensor for monitoring and the film thickness sensor for calibration for actual film formation, it is necessary to previously determine a calibration coefficient for correcting the difference between the film thickness value calculated by each of the film thickness monitors and the actually measured value of the thickness of a film to be formed on the substrate. Thus, in the film thickness sensor for monitoring 20, the vapor deposition material 31 was heated to a temperature at which the vapor deposition rate reached 1.0 nm/sec. as a value indicated by the film thickness controller 61. Regarding the vapor deposition rate, the film thickness controller 61 receives a signal from the film thickness sensor for monitoring 20, converts the signal to a vapor deposition rate value, and outputs the vapor deposition rate value to a display portion of the film thickness controller 61. Further, the film thickness controller 61 calculates the difference between a target vapor deposition rate and the vapor deposition rate converted from the amount of the vapor deposition material actually adhering to the film thickness sensor for monitoring. Then, the film thickness controller 61 sends a signal for reducing the difference to the temperature controller 62 to control the heater power to the vapor depositing source 30.

When the vapor deposition rate reached 1.0 nm/sec. in the film thickness sensor for monitoring 20, one substrate 40 was delivered from the substrate stock device (not shown) to the vacuum chamber 50 through a gate valve (not shown) using a substrate conveying mechanism (not shown), and film formation was performed. The film formation was performed until the film thickness of a thin film to be deposited on the film thickness sensor for monitoring 20 reached 100 nm, and the substrate 40 on which a film has been formed was taken out from the vacuum chamber 50 immediately. The film thickness of the film formed on the substrate 40 was measured by an ellipsometer and compared with the film thickness value of the thin film deposited on the film thickness sensor for monitoring 20, and a new calibration coefficient b₂ of the film thickness sensor for monitoring 20 was calculated by Expression (1) shown below.

b₂=b₁×(t₁/t₂) (1)

In Expression (1), t₁ represents a film thickness of the thin film on the substrate 40, t₂ represents a target film thickness (here, 100 nm), b₁ represents a calibration coefficient of the film thickness sensor for monitoring 20 during film formation previously set in the system, and b₂ represents a new calibration coefficient of the film thickness sensor for monitoring 20.

By using the above-mentioned mathematical expression shown in Expression (1), the film thickness of the thin film on the substrate 40 can be matched with the film thickness on the film thickness sensor for monitoring 20.

Regarding the film thickness on the substrate 40 and the film thickness sensor for calibration 10, a calibration coefficient can be determined by the same method as that of the film thickness sensor for monitoring 20. Specifically, the sensor shutter (not shown) of the film thickness sensor for calibration 10 is opened during the film formation step of the substrate 40, and the film thickness is matched by the above-mentioned mathematical expression (Expression (1)) in the same way as in the film thickness sensor for monitoring 20. Here, in the case of the film thickness sensor for calibration 10, b₁ is replaced by b₁′ (calibration coefficient of the film thickness sensor for calibration 10 previously set in the device), and b₂ is replaced by b₂′ (new calibration coefficient of the film thickness sensor for calibration 10). It should be noted that, after the completion of film formation, the opened sensor shutter (not shown) is closed.

The new calibration coefficient of the film thickness sensor for monitoring 20 obtained by the above-mentioned method was replaced for the calibration coefficient of the film thickness sensor for monitoring 20 during film formation via the film thickness controller 61, and subsequently, the vapor deposition material 31 was heated again to a temperature at which the vapor deposition rate reached 1.0 nm/sec. Then, the new calibration coefficient of the film thickness sensor for calibration 10 is replaced for the calibration coefficient of the film thickness sensor for calibration 10 during film formation via the film thickness controller 61.

The steps of calculating the calibration coefficients described above were repeated until the difference between the film thickness of a thin film to be formed on the substrate 40 under the same film formation conditions and each of the thicknesses of films adhering to the film thickness sensor for calibration 10 and the film thickness sensor for monitoring 20 fell within ±2.0%.

Next, the vapor deposition rate was kept at 1.0 nm/sec. using the film thickness sensor for monitoring 20, and the substrates 40 were delivered continuously one by one from the substrate stock device, and film formation was performed on the substrate 40. During that time, regarding the substrate 40 delivered every time the frequency of the crystal oscillator of the film thickness sensor for monitoring 20 was decreased by 0.015 MHz, film formation was performed for film thickness monitoring. Before the film formation was performed on the substrate 40 for film thickness monitoring, the sensor shutter (not shown) provided in the vicinity of the film thickness sensor for calibration 10 was opened, and a calibration value based on the vapor deposition rate measured by the film thickness sensor for calibration 10 was determined. The vapor deposition rate of the film thickness sensor for monitoring 20 was calibrated by the calibration value.

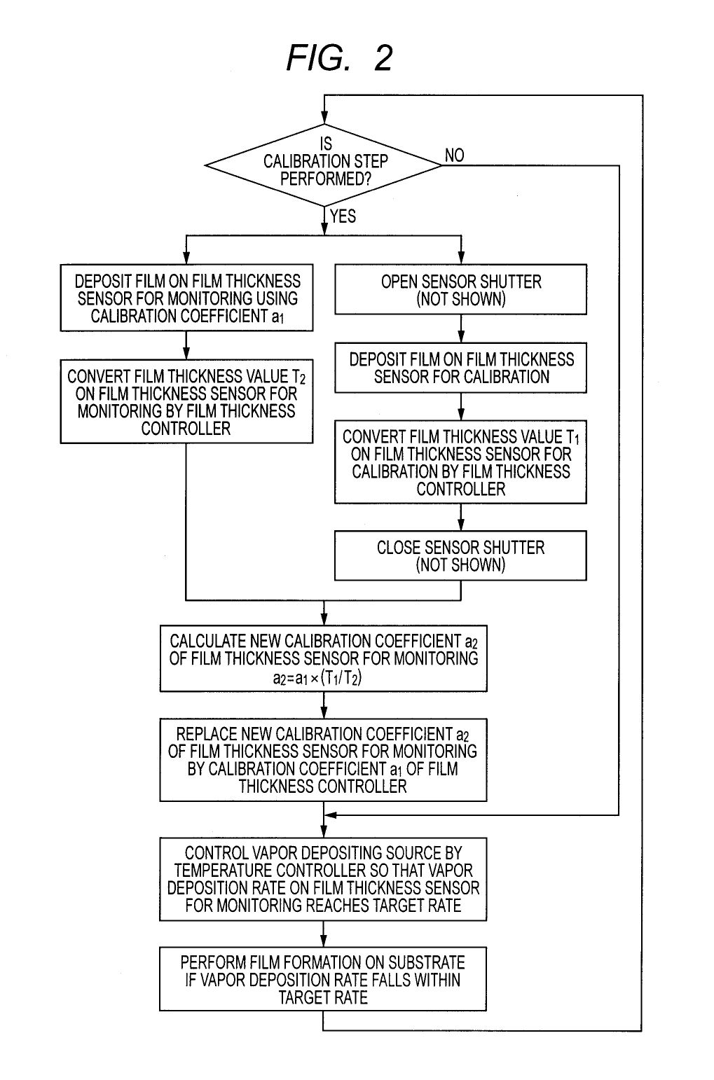

Hereinafter, a specific example of the step of calibrating the vapor deposition rate of the film thickness sensor for monitoring 20 (calibration step) is described with reference to the drawings. FIG. 2 is a flow chart illustrating an example of the calibration step. In this example, the calibration step was conducted according to the flow chart of FIG. 2.

First, thin films (vapor deposition films) of Alq₃ were deposited respectively on the film thickness sensor for monitoring 20 and the film thickness sensor for calibration 10. At this time, the film thickness of the thin film adhering to each sensor was converted using the film thickness controller 61. Next, the film thickness of the thin film adhering to the film thickness sensor for monitoring 20 was compared with the film thickness of the thin film adhering to the film thickness sensor for calibration 10, and a new calibration coefficient a₂ of the film thickness sensor for monitoring 20 was calculated by Expression (2) shown below.

a₂=a₁×(T₁/T₂) (2)

In Expression (2), a₁ represents a calibration coefficient of the film thickness sensor for monitoring 20 during film formation, a₂ represents a new calibration coefficient of the film thickness sensor for monitoring 20, T₁ represents a film thickness of the thin film on the film thickness sensor for calibration 10, and T₂ represents a film thickness of the thin film on the film thickness sensor for monitoring 20.

Here, assuming that T₁ and T₂ are thicknesses of films adhering within the same period of time, the film thickness of the thin film on the film thickness sensor for monitoring 20 can be matched with the film thickness of the thin film on the film thickness sensor for calibration 10 based on Expression (2) above. By performing the calibration step described above, an error of the vapor deposition rate involved in frequency attenuation of the film thickness sensor for monitoring 20 can be calibrated.

It should be noted that the sensor shutter (not shown) provided in the vicinity of the film thickness sensor for calibration 10 is closed after the film thickness (T₁) of the thin film on the film thickness sensor for calibration 10 is converted. Then, the new calibration coefficient a₂ of the film thickness sensor for monitoring 20 is replaced for the calibration coefficient a₁ of the film thickness sensor for monitoring 20 during film formation of the film thickness controller 61, and the calibration coefficient a₂ is used as the new calibration coefficient a₁ of the film thickness sensor for monitoring 20.

Next, after the new calibration coefficient of the film thickness sensor for monitoring 20 was input to the film thickness controller 61, the vapor depositing source 30 was controlled by the temperature controller 62 so that the vapor deposition rate reached 1.0 nm/sec. as a target rate. Then, after the target rate reached 1.0 nm/sec. in the film thickness sensor for monitoring 20, the film formation on the substrate 40 was performed. The above-mentioned film formation was repeated until films were formed on ten substrates 40 for monitoring.

The film thicknesses in the vicinity of the centers of the ten substrates 40 for film thickness monitoring obtained by film formation by the above-mentioned method were measured by an ellipsometer. As a result, the measured film thickness fell within a range of 100 nm±2.0% with respect to the target film thickness of 100 nm. This shows that the phenomenon in which the frequency of the crystal oscillator is attenuated to deviate from the target film thickness along with the adhesion of the vapor deposition material 31 to the film thickness sensor for monitoring 20 was overcome by the film thickness sensor for calibration 10 placed at a position with high calibration accuracy. It was found from this result that the Alq₃ film was formed with good accuracy with respect to the target film thickness over a long period of time. Regarding the substrates other than those for film thickness monitoring, second electrodes were formed and then organic EL elements were covered with sealing members made of glass to obtain organic light-emitting devices. In multiple organic light-emitting devices thus obtained, no brightness shift and color shift were observed.

As described above, by forming a thin film constructing an organic EL element using the vacuum vapor deposition system of this example in producing an organic EL element, an organic EL element with the film thickness of each layer controlled over a long period of time can be produced. As a result, an organic light-emitting device can be produced with good yield.

In this example, the construction illustrated in each of FIGS. 1A and 1B is used as the vapor depositing source 30, but is not limited thereto. Further, in the case of using a high-precision mask as the mask 41, high-precision mask vapor deposition may be conducted using an alignment stage in combination, or fine pattern formation by precision alignment vapor deposition may be conducted.

### Comparative Example 1

In order to verify the effects of Example 1, a comparative test in the case of forming a film by a conventional vacuum vapor deposition system disclosed in Japanese Patent Application Laid-Open No. 2008-122200 was conducted. In this comparative example, considering the figure of Japanese Patent Application Laid-Open No. 2008-122200, a film thickness sensor for calibration and a film thickness sensor for monitoring were placed respectively so as to satisfy relationships of L₁=L₂ and θ₁>θ₂. In this construction, vapor of Alq₃ was generated from a vapor depositing source toward an object on which a film is formed in a vacuum chamber, and the vapor depositing source was heated to a temperature at which the vapor deposition rate reached 1.0 nm/sec. in the film thickness sensor for monitoring. The film formation on the substrate was performed by the same method as that of the present invention, and the film thicknesses in the vicinity of the centers of ten substrates for film thickness monitoring were observed by an ellipsometer. As a result, the measured film thickness was not within a range of ±2.0% in some cases with respect to a target film thickness of 100 nm. The reason for this is considered as follows: the amount of a vapor deposition material entering the film thickness sensor for calibration is small; and hence the film thickness sensor for monitoring cannot be calibrated with good accuracy in some cases. It was found from these results that the vacuum vapor deposition system of the present invention is more excellent than the conventional vacuum vapor deposition system in forming a film from a vapor deposition material with a predetermined film thickness on a substrate.

### Example 2

Meanwhile, in Example 1, every time the frequency of the crystal oscillator of the film thickness sensor for monitoring 20 decreased by 0.015 MHz, the calibration step before film formation and film formation on a substrate for monitoring were performed. However, the present invention is not limited thereto. Further, the arrangement of film thickness sensors only needs to satisfy relationships of L₁≦L₂ and θ₁≦θ₂, and is not limited to the embodiment in which the relationships of L₁<L₂ and θ₁<θ₂ are satisfied as in the vacuum vapor deposition system 1 of FIG. 1A.

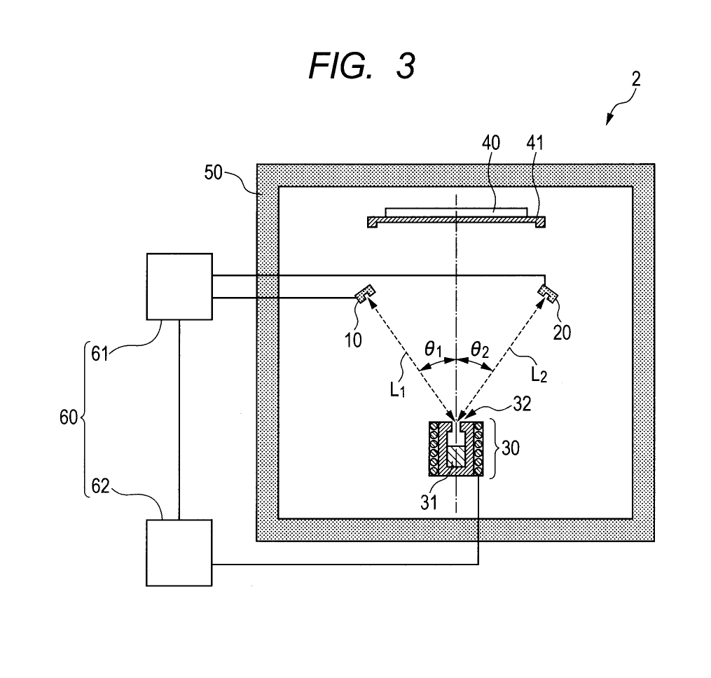

FIG. 3 is a schematic diagram illustrating a second embodiment of the vacuum vapor deposition system of the present invention. A vacuum vapor deposition system 2 of FIG. 3 is an embodiment in which two kinds of sensors (film thickness sensor for calibration 10 and film thickness sensor for monitoring 20) satisfy relationships of L₁=L₂=200 mm and θ₁=θ₂=30° in the case where film formation is performed under the same vapor deposition conditions as those in Example 1. It should be noted that, in the vacuum vapor depositing system 2 of FIG. 3, the two kinds of sensors (film thickness sensor for calibration 10 and film thickness sensor for monitoring 20) are placed opposed to each other with a perpendicular line from a center of an opening 32 to a film formation surface of a substrate 40 interposed therebetween. However, the arrangement positions of the two kinds of sensors are not limited thereto in the present invention.

### Example 3

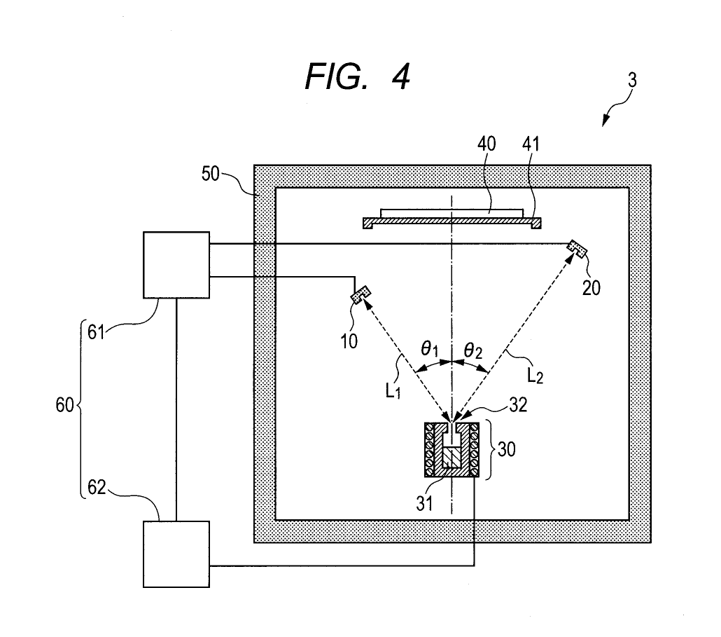

FIG. 4 is a schematic diagram illustrating a third embodiment of the vacuum vapor deposition system of the present invention. A vacuum vapor deposition system 3 of FIG. 4 is an embodiment in which two kinds of sensors (film thickness sensor for calibration 10 and film thickness sensor for monitoring 20) satisfy relationships of L₁=200 mm<L₂=300 mm and θ₁=θ₂=30° in the case where film formation is performed under the same vapor deposition conditions as those in Example 1.

### Example 4

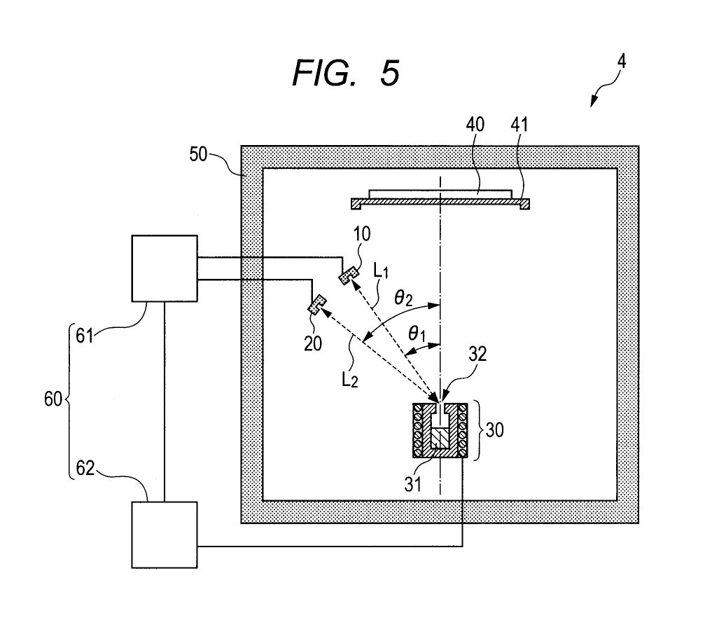

FIG. 5 is a schematic diagram illustrating a fourth embodiment of the vacuum vapor deposition system of the present invention. A vacuum vapor deposition system 4 of FIG. 5 is an embodiment in which two kinds of sensors (film thickness sensor for calibration 10 and film thickness sensor for monitoring 20) satisfy relationships of L₁=L₂=200 mm and θ₁=30°<θ₂=40° in the case where film formation is performed under the same vapor deposition conditions as those in Example 1.

In any of the vacuum vapor deposition systems of FIGS. 1 and 3 to 5, the entry amount of a vapor deposition material to the film thickness sensor for calibration 10 increases, which can enhance calibration accuracy. Further, in the vacuum vapor deposition systems of Examples 2 to 4 similarly to Example 1, at least one of the film thickness sensor for calibration and the film thickness sensor for monitoring may be provided with a sensor shutter for blocking the vapor of the vapor deposition material. Further, a vapor deposition amount restricting mechanism (not shown) for blocking the vapor of the vapor deposition material 31 intermittently may be provided instead of the sensor shutter. Further, the step of calculating a calibration coefficient required for matching the film thickness values of the substrate 40, the film thickness sensor for calibration 10, and the film thickness sensor for monitoring 20 is not limited to the method of Example 1, and each film thickness value only needs to fall within a target value. For example, the film thickness values of the substrate 40 and the film thickness sensor for monitoring 20 may be matched with each other previously, and then, the film thickness values of the film thickness sensor for monitoring 20 and the film thickness sensor for calibration 10 may be matched with each other. Further, a substrate holding mechanism (not shown) which holds the substrate 40 may be provided with a shutter for blocking the vapor of the vapor deposition material.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Applications. No. 2010-247817, filed Nov. 4, 2010, and No. 2011-211797, filed Sep. 28, 2011, which are hereby incorporated by reference herein in their entirety.

What is claimed is:

1. A vacuum vapor deposition system, comprising:
a vacuum chamber;
a substrate holding mechanism which holds a substrate;
a vapor depositing source which generates vapor of a vapor deposition material to be formed into a film on the substrate;
a film thickness sensor for monitoring which measures an adhesion amount of the vapor deposition material adhering to a sensor portion when the vapor deposition material is formed into a film on the substrate; and
a film thickness sensor for calibration which calibrates the adhesion amount measured by the film thickness sensor for monitoring; and
a control system which calculates a vapor deposition rate of the vapor deposition material based on the adhesion amount of the vapor deposition material measured by the film thickness sensor for monitoring and which controls a temperature of the vapor depositing source based on the calculated vapor deposition rate,
wherein:
a distance L₁ from a center of an opening of the vapor depositing source to the film thickness sensor for calibration and a distance L₂ from the center of the opening of the vapor deposition source to the film thickness sensor for monitoring satisfy a relationship of L₁≦L₂; and
an angle θ₁ formed by a perpendicular line from the center of the opening of the vapor deposition source to a film formation surface of the substrate and a straight line connecting the center of the opening of the vapor depositing source to the film thickness sensor for calibration, and an angle θ₂ formed by a perpendicular line from the center of the opening of the vapor depositing source to the film formation surface of the substrate and a straight line connecting the center of the opening of the vapor depositing source to the film thickness sensor for monitoring satisfy a relationship of L₁≦θ₂.

2. A method of producing an organic light-emitting device using the vacuum vapor deposition system according to claim 1, the method comprising:
depositing a film made of an organic electroluminescent material on a substrate, a film thickness sensor for monitoring, and a film thickness sensor for calibration; and
comparing a film thickness of the film calculated based on an adhesion amount measured by the film thickness sensor for monitoring with a film thickness of the film calculated based on an adhesion amount measured by the film thickness sensor for calibration to determine a calibration coefficient of the film thickness sensor for monitoring.
